(19) United States
(12) Patent Application Publication
(10) Pub. No.: US 2026/0362584 A1
(43) Pub. Date: Nov. 12, 2026

(54) ELECTRONIC DEVICE

(71) Applicant: DENSO CORPORATION, Kariya-city (JP)

(72) Inventors: Ryo WATANABE, Nisshin-shi (JP); Takuya YAMAGUCHI, Kariya-city (JP); Toshiaki TANABE, Kariya-city (JP)

(21) Appl. No.: 19/670,555

(22) Filed: May 7, 2026

(30) Foreign Application Priority Data
May 9, 2025 (JP) 2025-078973
Apr. 6, 2026 (JP) 2026-062533

(51) Int. Cl. H05K 1/02; H05K 1/11

(52) U.S. Cl. CPC H05K 1/0213; H05K 1/0284; H05K 1/11

(57) ABSTRACT

An electronic device includes a circuit board and a metal member. The circuit board includes a printed board and a noise source mounted on the printed board. The metal member provides an internal space accommodating the noise source and defining, between the metal member and the circuit board, a gap connecting the internal space to an external space. The printed board includes a periodic structure part that includes a ground layer providing a ground potential, lands facing the ground layer and disposed periodically along the gap, and short-circuit portions electrically connecting the lands to the ground layer. A facing distance between the periodic structure part and the metal member at the gap is equal to or less than one quarter of a wavelength corresponding to a frequency of electromagnetic noise generated by the noise source.

### CROSS REFERENCE TO RELATED APPLICATIONS

The present application claims the benefit of priority from Japanese Patent Application No. 2025-078973 filed on May 9, 2025 and Japanese Patent Application No. 2026-062533 filed on Apr. 6, 2026, the entire contents of which are incorporated herein by reference.

### TECHNICAL FIELD

The present disclosure relates to an electronic device.

### BACKGROUND

JP 2025-35419 A discloses an electronic device capable of suppressing the influence of noise. The contents of JP 2025-35419 A are incorporated herein by reference as description of technical elements in this specification.

### SUMMARY

According to an aspect of the present disclosure, an electronic device may include: a circuit board including a printed board and a noise source mounted on the printed board; and a metal member providing an internal space accommodating the noise source and defining, between the metal member and the circuit board, a gap connecting the internal space to an external space. The printed board may include a periodic structure part including: a ground layer providing a ground potential; a plurality of lands disposed to face the ground layer and disposed periodically along the gap; and a plurality of short-circuit portions electrically connecting the plurality of lands to the ground layer. A facing distance between the periodic structure part and the metal member at the gap may be equal to or less than one quarter of a wavelength corresponding to a frequency of electromagnetic noise generated by the noise source.

### BRIEF DESCRIPTION OF THE DRAWINGS

Objects, features and advantages of the present disclosure will become more apparent from the following detailed description made with reference to the accompanying drawings, in which like parts are designated by like reference numbers and in which:

FIG. 1 is a perspective view of an electronic device according to a first embodiment;

FIG. 2 is a cross-sectional view taken along a line II-II of FIG. 1;

FIG. 3 is a plan view of the electronic device when viewed along a Z1 direction in FIG. 1;

FIG. 4 is a diagram showing a positional relationship among an electronic component, a gap, and a periodic structure part;

FIG. 5 is a perspective view of the periodic structure part;

FIG. 6 is a perspective view of a model used for electromagnetic-field simulation;

FIG. 7 is a cross-sectional view taken along a line VII-VII of FIG. 6;

FIG. 8 is a diagram showing effects of the periodic structure part;

FIG. 9 is a cross-sectional view of an electronic device according to a modification;

FIG. 10 is a perspective view of a periodic structure part of an electronic device according to a second embodiment;

FIG. 11 is a cross-sectional view taken along a line XI-XI of FIG. 10;

FIG. 12 is a diagram showing transmission characteristics;

FIG. 13 is a perspective view of a periodic structure part of an electronic device according to a third embodiment;

FIG. 14 is a cross-sectional view taken along a line XIV-XIV of FIG. 13;

FIG. 15 is a diagram showing transmission characteristics;

FIG. 16 is a cross-sectional view of a periodic structure part according to a modification;

FIG. 17 is a perspective view of an electronic device according to a fourth embodiment;

FIG. 18 is an exploded perspective view of the electronic device;

FIG. 19 is a perspective view of a base of the electronic device on one surface side;

FIG. 20 is a perspective view of the base on a back surface side;

FIG. 21 is a perspective view of a flow-channel cover;

FIG. 22 is a cross-sectional view taken along a line XXII-XXII of FIG. 17;

FIG. 23 is a cross-sectional view of an electronic device according to a modification;

FIG. 24 is a plan view of an electronic device according to a fifth embodiment; and

FIG. 25 is a perspective view of a structure part of the electronic device.

### DETAILED DESCRIPTION

In JP 2025-35419 A, in order to suppress propagation of noise generated by an electronic component to an external space through a gap between a cooling plate, which is a metal member, and a land of a printed board, a conductive gasket is disposed between the cooling plate and the land. In view of the above and/or other viewpoints not mentioned, further improvement is required for electronic devices.

The present disclosure provides an electronic device capable of suppressing propagation of noise generated by an electronic component to an external space with a simple configuration.

According to an aspect of the present disclosure, an electronic device includes: a circuit board that includes a printed board and a noise source mounted on the printed board; and a metal member that provides an internal space accommodating the noise source and defines, between the metal member and the circuit board, a gap connecting the internal space and an external space. The printed board includes a periodic structure part including: a ground layer that provides a ground potential; a plurality of lands that are disposed to face the ground layer and arranged periodically along the gap; and a plurality of short-circuit portions that electrically connect the lands to the ground layer. A facing distance between the periodic structure part and the metal member at the gap is equal to or less than one quarter of a wavelength corresponding to a frequency of electromagnetic noise generated by the noise source.

In such an electronic device, the printed board is provided with the periodic structure part including the ground layer, the lands, and the short-circuit portions. The periodic structure part has a mushroom structure, which is a type of metamaterial. The facing distance between the periodic structure part and the metal member has a length equal to or less than one quarter of the wavelength corresponding to the frequency of electromagnetic noise generated by the noise source, and the surface impedance of the periodic structure part is high with respect to the frequency. Therefore, even without using a gasket, it is possible to suppress propagation of the electromagnetic noise to the external space through the gap. In other words, with a simple configuration, it is possible to suppress propagation of the electromagnetic noise to the external space.

According to another aspect of the present disclosure, an electronic device includes: a circuit board that includes a printed board and a noise source mounted on the printed board; and a metal member that provides an internal space accommodating the noise source and defines, between the metal member and the circuit board, a gap connecting the internal space and an external space. The printed board includes a structure part including: a ground layer that provides a ground potential; a land disposed to face the ground layer; and a short-circuit portion that electrically connects the land to the ground layer, in which the land is disposed closer to the gap than the ground layer. A facing distance between the structure part and the metal member at the gap is equal to or less than one quarter of a wavelength corresponding to a frequency of electromagnetic noise generated by the noise source.

In such an electronic device, the printed board is provided with the structure part including the ground layer, the land, and the short-circuit portion. The structure part has a mushroom structure, which is a type of metamaterial. The facing distance between the structure part and the metal member has a length equal to or less than one quarter of the wavelength corresponding to the frequency of electromagnetic noise generated by the noise source, and the surface impedance of the structure part is high with respect to the frequency. Therefore, even without using a gasket, it is possible to suppress propagation of the electromagnetic noise to the external space through the gap. In other words, with a simple configuration, it is possible to suppress propagation of the electromagnetic noise to the external space.

According to still another aspect of the present disclosure, an electronic device includes: a circuit board that includes a printed board and a noise source mounted on the printed board; and a metal member that provides an internal space accommodating the noise source and defines, between the metal member and the circuit board, a gap connecting the internal space and an external space. The printed board includes a periodic structure part including: a ground layer that provides a ground potential; a plurality of lands that are disposed to face the ground layer and arranged periodically along the gap; and a plurality of short-circuit portions that electrically connects the lands to the ground layer. A facing distance between the periodic structure part and the metal member at the gap is greater than 0 mm and equal to or smaller than 12.5 mm.

In such an electronic device, the printed board is provided with the periodic structure part including the ground layer, the plurality of lands, and the short-circuit portion. The periodic structure part has a mushroom structure, which is a type of metamaterial. The facing distance between the periodic structure part and the metal member is greater than 0 mm and equal to or smaller than 12.5 mm, and the surface impedance of the periodic structure part is high with respect to a frequency corresponding to the facing distance. Therefore, even without using a gasket, it is possible to suppress propagation of the electromagnetic noise to the external space through the gap. In other words, with a simple configuration, it is possible to suppress propagation of the electromagnetic noise to the external space.

Embodiments of the present disclosure will be described hereinafter with reference to the drawings. In the following, corresponding components may be denoted by the same reference numerals throughout the embodiments, and the descriptions thereof will not be repeated. When only a part of a configuration is described in an embodiment, the other parts of the configuration may employ configurations of other embodiments described earlier. Further, not only combinations of configurations explicitly described in the embodiments but also partial combinations among configurations of multiple embodiments can be made unless such combinations cause inconsistency.

### First Embodiment

First, a schematic configuration of an electronic device according to a first embodiment will be described.

### Electronic Device

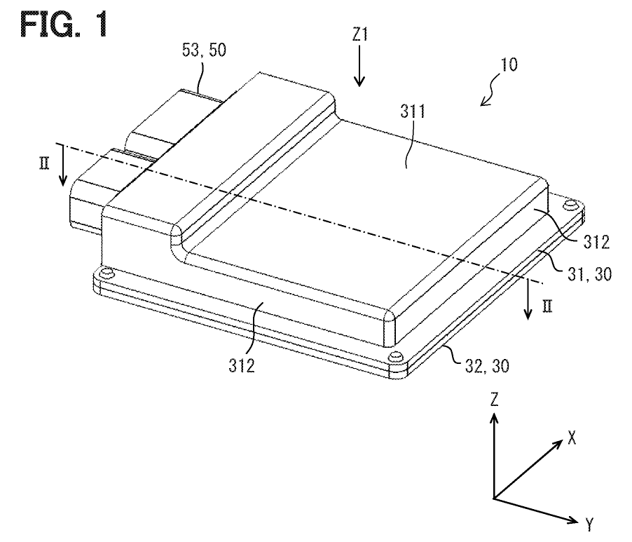

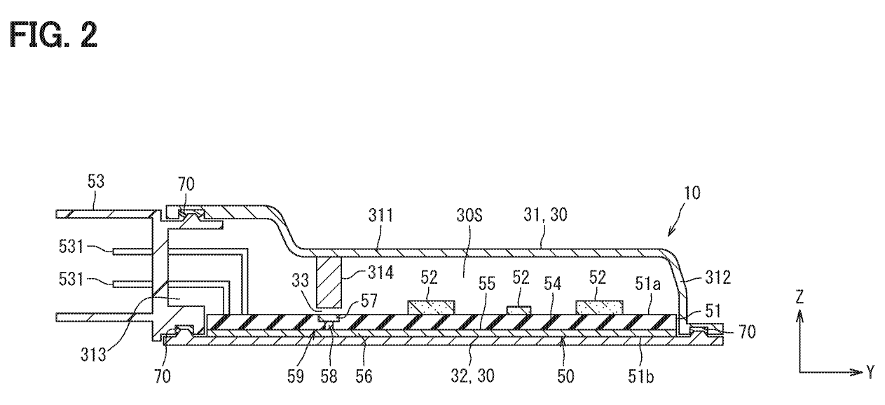

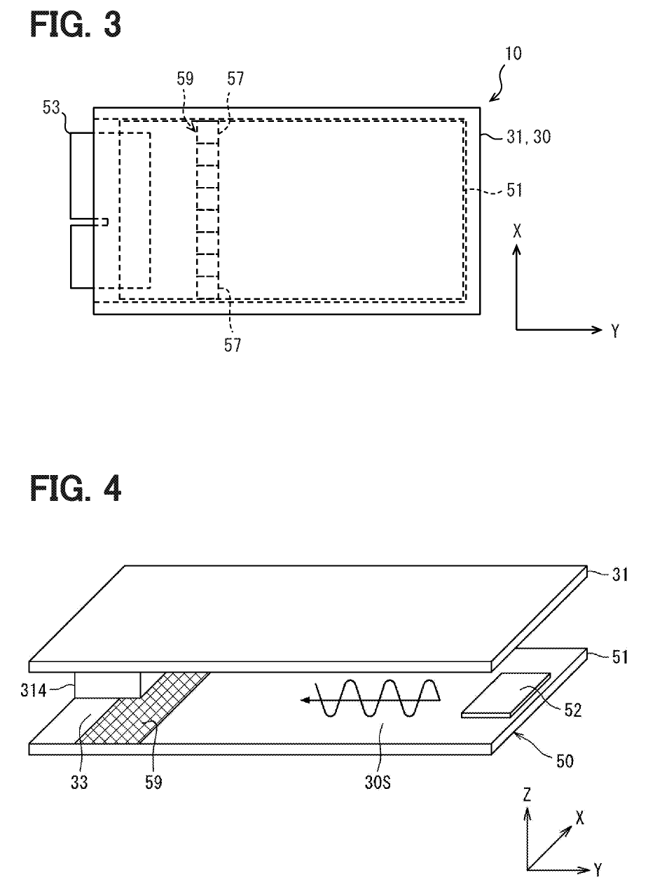

FIG. 1 is a perspective view of an example of an electronic device 10. FIG. 2 is a cross-sectional view taken along a line II-II of FIG. 1. FIG. 3 is a plan view of the electronic device when viewed along a Z1 direction shown in FIG. 1. In FIG. 2, for convenience, among conductors of a printed board, only conductors constituting a periodic structure part are shown.

In the following, a thickness direction of the printed board is referred to as the Z direction. A direction orthogonal to the Z direction is referred to as an X direction, and a direction orthogonal to both the Z direction and the X direction is referred to as a Y direction. Unless otherwise specified, a shape in a plan view when viewed along the Z direction, i.e., a shape along an XY plane defined by the X direction and the Y direction, is referred to as a planar shape. A plan view when viewed along the Z direction may simply be referred to as a plan view.

As shown in FIGS. 1 - 3, the electronic device 10 includes a housing 30 and a circuit board 50. The electronic device 10 may be, for example, an electronic control unit (ECU). The electronic device 10 may be mounted on a mobile body, for example. The mobile body is, for example, a vehicle, an aircraft, a ship, a construction machine, an agricultural machine, or the like. The mobile body may be a manned mobile body or an unmanned mobile body.

The housing 30 accommodates at least a part of other elements of the electronic device 10. The housing 30 provides an accommodation space therein and protects elements of the electronic device 10 disposed in the accommodation space. A planar shape of the housing 30 is not particularly limited. The illustrated housing 30 has a substantially rectangular planar shape.

The housing 30 is, for example, composed of a plurality of members. The number of the members constituting the housing 30 may be two, or three or more. The housing 30 is formed using a metal material. The housing 30 has an electromagnetic wave shielding function. The housing 30 may have a heat dissipation function. The illustrated housing 30 is configured to be dividable into two parts in the Z direction. The housing 30 includes two members, specifically a case 31 and a cover 32. By assembling the case 31 and the cover 32, the housing 30 having the accommodation space is formed. The case 31 has a box shape defining an opening on one side. The case 31 includes a bottom wall 311 and a side wall 312.

The bottom wall 311 has a substantially rectangular planar shape. The side wall 312 is connected to an outer peripheral edge of the bottom wall 311. The side wall 312 extends generally in the Z direction from the bottom wall 311. One of four side walls 312 connected to the bottom wall 311 is formed with a notch 313. The notch 313 communicates with the opening defined on one side of the case 31. A shape of the cover 32 is not particularly limited. The cover 32 is provided so as to cover the opening of the case 31. The cover 32 may be, for example, a substantially flat plate.

The case 31 has a partition wall 314 protruding in the Z direction from an inner surface of the bottom wall 311. The partition wall 314 may be continuously connected to the bottom wall 311, or may be formed by joining a metal member separate from the bottom wall 311 to the bottom wall 311. The partition wall 314 is a metal wall that separates an internal space in which an electronic component 52 is disposed and an external space. The partition wall 314 is located between the internal space and the external space. The external space includes a portion other than the internal space in the accommodation space of the housing and also includes a space outside the housing 30. The illustrated partition wall 314 extends in the X direction while having a predetermined length in the Z direction. In the X direction, both ends of the partition wall 314 are connected to the side walls 312.

The partition wall 314 extends from the bottom wall 311 toward the circuit board 50. The partition wall 314 has a predetermined length such that the partition wall 314 is not in contact with the circuit board 50 (the printed board 51). As the case 31 has the partition wall 314, the case 31 forms a gap 33 between the circuit board 50 and the case 31. The gap 33 allows communication between an internal space 30S and the external space. The gap 33 is formed in a facing region where a tip end of the partition wall 314 faces the printed board 51. The gap 33 is provided along the partition wall 314. That is, the gap 33 is provided to extend from one end of the printed board 51 to the other end, in the X direction.

The circuit board 50 includes the printed board 51, an electronic component 52, and a connector 53. The printed board 51 may also be referred to as a board, a wiring board, or the like. The printed board 51 has a first surface 51a and a second surface 51b. The second surface 51b is a surface opposite the first surface 51a in the thickness direction (Z direction). The first surface 51a is a surface on the case 31 side in the Z direction, and the second surface 51b is a surface on the cover 32 side in the Z direction. The second surface 51b may also be referred to as a back surface. A planar shape of the printed board 51 is not particularly limited. The illustrated printed board 51 has a substantially rectangular planar shape. The printed board 51 is fixed to the case 31 or the cover 32 by screw fastening or the like.

The printed board 51 includes an insulating base material 54 and a conductor 55. The insulating base material 54 is a substrate that supports (holds) the conductor 55. The insulating base material 54 is formed using an electrically insulating material such as resin. As the insulating base material 54, for example, one containing only resin, or one containing a resin with glass cloth, nonwoven fabric, or the like can be employed.

The conductor 55 is disposed on the insulating base material 54. The conductor 55 constitutes a circuit, together with the electronic component 52. The conductor 55 is formed using a metal material having good conductivity such as Cu. The conductor 55 includes at least wiring. The wiring may be referred to as a conductor pattern, a wiring pattern, or the like. The wiring is formed, for example, by patterning a metal foil. The conductor 55 may include a via conductor in addition to the wiring. The via conductor is formed by disposing a conductor such as plating in a through hole (via) formed in an insulating layer constituting the substrate. The via conductor electrically connects wirings disposed in different layers. The conductor 55 may include a conductor that provides no circuit function.

The conductor 55 is disposed in multiple layers with respect to the insulating base material 54. The conductor 55 includes a periodic structure part 59 that is configured to include a ground layer 56, a plurality of lands 57, and a short-circuit portion 58. Details of the periodic structure part 59 will be described later. The printed board 51 includes, separately from the lands 57 constituting the periodic structure part 59, a land (not shown) to which the electronic component 52 is electrically connected. The land to which the electronic component 52 is connected provides a wiring function.

The electronic component 52 is mounted on the printed board 51. The electronic component 52 constitutes a circuit together with the conductor 55 of the printed board 51. The electronic device 10 includes a plurality of electronic components 52. The electronic components 52 are electrically connected to the lands (not shown) of the printed board 51. The electronic components 52 include at least a surface-mount electronic component soldered to the land. The electronic component 52 includes at least an electronic component disposed on the first surface 51a. The illustrated electronic component 52 is disposed only on the first surface 51a, of the first surface 51a and the second surface 51b.

The connector 53 is mounted on the printed board 51. The connector 53 electrically connects the circuit configured to include the printed board 51 and the electronic component 52 with an external device. The connector 53 includes a terminal 531 that electrically connects the conductor 55 of the printed board 51 and the external device. A part of the connector 53 is accommodated in the housing 30 and another part is exposed outside the housing 30. The connector 53 is exposed to the outside through an opening of the housing 30. The illustrated opening of the housing 30 is defined by the notch 313 of the case 31 and the cover 32.

As shown in FIG. 2, the electronic device 10 may include a seal member 70. The seal member 70 is interposed, at peripheral portions of the case 31 and the cover 32, between facing surfaces of the case 31 and the cover 32, between facing surfaces of the case 31 and the connector 53, and between facing surfaces of the cover 32 and the connector 53. The seal member 70 seals the accommodation space of the housing 30 in a watertight manner with respect to a space outside the housing 30 and restrict liquid from entering.

The circuit board 50 described above includes a noise source that generates high-frequency noise (electromagnetic noise). The noise source is mounted on the printed board 51. The noise source includes the electronic component 52 and/or wiring that functions as an antenna. The illustrated electronic component 52 includes an electronic component that generates electromagnetic noise, such as a processor, a clock oscillator, and a switching element. In this case, an operating frequency of the electronic component 52 that generates electromagnetic noise corresponds to a frequency of the electromagnetic noise generated by the noise source.

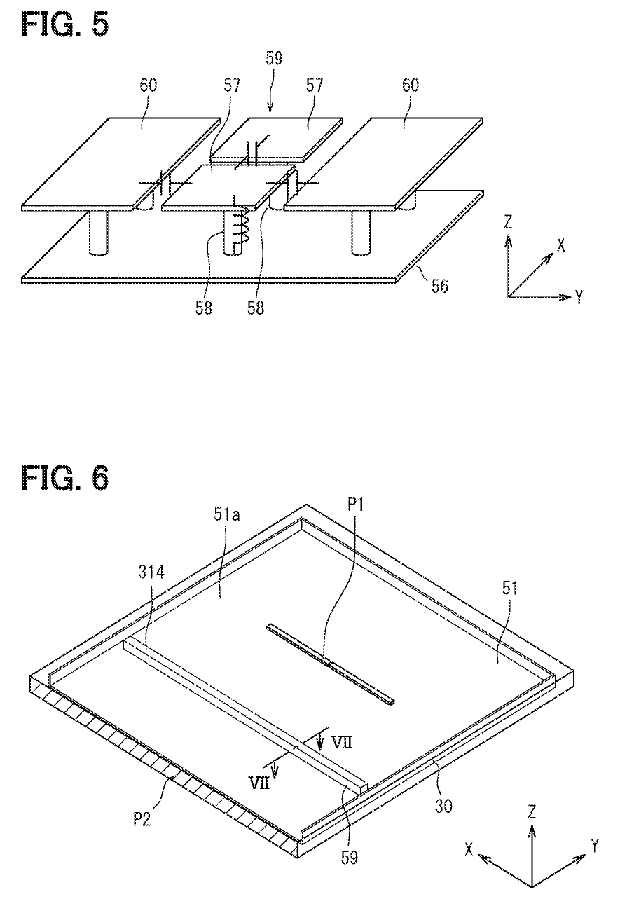

FIG. 4 is a diagram showing a positional relationship among the electronic component 52, the gap 33, and the periodic structure part 59. In FIG. 4, the periodic structure part 59 is shown in a simplified manner. In FIG. 4, for clarification, the periodic structure part 59 is hatched. FIG. 5 is a perspective view of the periodic structure part 59. In FIG. 5, for convenience, only two lands 57 are shown. Also, of the elements of the printed board 51, only the conductor is shown. As shown in FIGS. 2 - 5, the printed board 51 has the periodic structure part 59 that is configured to include the ground layer 56, the land 57, and the short-circuit portion 58. The illustrated printed board 51 includes the periodic structure part 59, as a structure part. The periodic structure part 59 includes a plurality of lands 57. The insulating base material 54 (dielectric) is interposed between the ground layer 56 and the lands 57. Reference number 60 shown in FIG. 5 denotes a wiring provided in the surface layer on the first surface 51a side separately from the land 57.

The ground layer 56 provides a reference potential (ground potential) in the printed board 51. The ground layer 56 is disposed in a layer different from the land 57. The ground layer 56 is disposed inside the insulating base material 54 or in a surface layer on the second surface 51b side. The ground layer 56 is disposed over substantially the entire region of a predetermined layer. The ground layer 56 is a so-called solid ground. The ground layer 56 is disposed to include all of the lands 57 in the plan view. The illustrated ground layer 56 is disposed in the surface layer on the second surface 51b side. The ground layer 56 is in contact with the cover 32.

The plurality of lands 57 include at least a land disposed in the surface layer of the printed board 51. All of the illustrated lands 57 are disposed in the surface layer on the first surface 51a side. The plurality of lands 57 are disposed to face the ground layer 56 in the Z direction. The plurality of lands 57 are arranged periodically along the gap 33. The lands 57 are arranged along the X direction. The plurality of lands 57 are arranged continuously along the X direction. The lands 57 are arranged adjacent to each other. The land 57 may be referred to as a patch portion. The land 57 has a substantially rectangular planar shape having sides along the X direction and sides along the Y direction. The illustrated land 57 is substantially square in the plan view.

The short-circuit portion 58 electrically connects, i.e., short-circuits, the ground layer 56 and the land 57. The illustrated short-circuit portion 58 is a via conductor. One end of the short-circuit portion 58 is connected to the ground layer 56 and the other end is connected to the land 57. The short-circuit portion 58 is provided individually for each of the plurality of lands 57. The short-circuit portion 58 has, for example, a substantially circular shape in the plan view. The illustrated short-circuit portion 58 is connected to substantially a center of the land 57 in the plan view. The short-circuit portion 58 is connected to the land 57 such that the center of the short-circuit portion 58 substantially coincides with the center of the land 57. The center of the land 57 corresponds to a centroid of the land 57. Since the land 57 has a substantially square planar shape, the center corresponds to an intersection of two diagonals of the land 57.

The number of the via conductors constituting the short-circuit portion 58 is not particularly limited. In the illustrated example, one short-circuit portion 58 is constituted by one via conductor. Alternatively, the short-circuit portion 58 may be constituted by a plurality of via conductors disposed in parallel between the ground layer 56 and the land 57.

As described above, the periodic structure part 59 forms a mushroom structure in which the ground layer 56 and the land 57 facing each other are connected by the short-circuit portion 58. The illustrated periodic structure part 59 also forms the mushroom structure. The mushroom structure is a type of metamaterial. The periodic structure part 59 is configured by arranging the mushroom structures periodically along the gap 33. The periodic structure part 59 has capacitance formed between the land 57 and an adjacent land 57 or the like, and inductance of the short-circuit portion 58, and functions as an LC resonant circuit as a whole. Preferably, the land 57 forms capacitance between the land 57 and an adjacent wiring 60. In the periodic structure part 59, a portion defined by one land 57 may be referred to as a cell or a unit cell. The periodic structure part 59 has a plurality of cells arranged along the X direction.

In general metals, impedance is high in the Z direction and low in a direction orthogonal to the Z direction. In contrast, in the periodic structure part 59, impedance can be made low in the Z direction and high in a direction orthogonal to the Z direction. That is, in the periodic structure part 59, surface impedance can be made high. Such a structure is known as a high impedance surface (HIS) structure. The mushroom structure is an example of the HIS structure.

The periodic structure part 59 has a very high surface impedance at a predetermined frequency, and electromagnetic waves of the predetermined frequency hardly propagate on a surface of the periodic structure part 59. That is, by setting a facing distance between the periodic structure part 59 and the partition wall 314, i.e., the length of the gap 33 in the Z direction, to be equal to or less than one quarter of the wavelength of the predetermined frequency, propagation of electromagnetic waves of the predetermined frequency can be suppressed, i.e., the electromagnetic waves can be blocked. In the illustrated electronic device 10, the facing distance between the periodic structure part 59 and the partition wall 314 is set to be equal to or less than one quarter of a wavelength corresponding to an operating frequency of the electronic component 52 serving as the noise source. The facing distance is greater than zero and equal to or less than one quarter of the wavelength corresponding to the operating frequency of the electronic component 52 serving as the noise source. Due to manufacturing variations, the facing distance may be zero. Thus, propagation of electromagnetic noise generated by the electronic component 52 to the external space outside the periodic structure part 59 can be suppressed. In a case where there are a plurality of electronic components 52 serving as the noise source, the facing distance may be set to be equal to or less than one quarter of a wavelength corresponding to the lowest frequency. The facing distance may be set in a range greater than 0 mm and equal to or smaller than 12.5 mm. 12.5 mm corresponds to one quarter of 6 GHz. In this case, electromagnetic noise of the frequency of 6 GHz or less can be blocked. For example, electromagnetic noise in several-GHz bands (1 to 6 GHz) can be blocked.

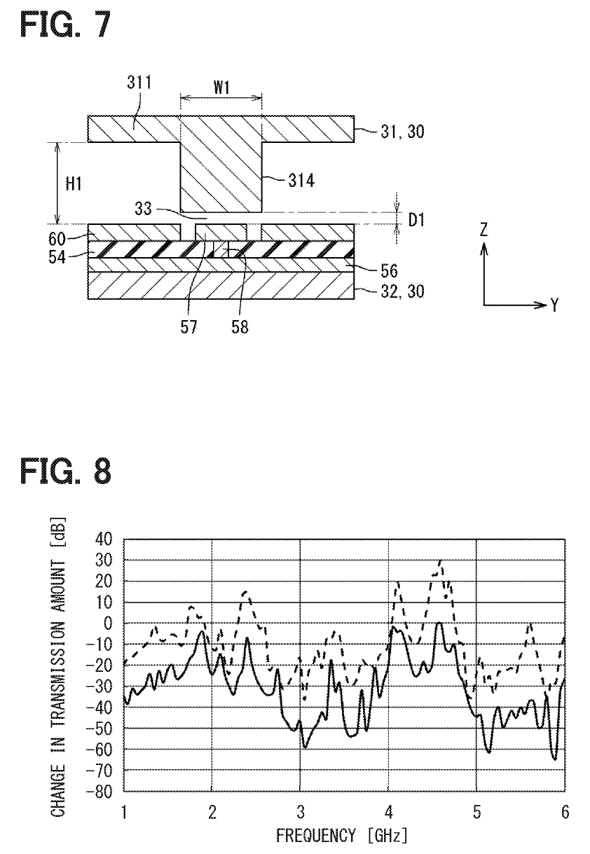

FIGS. 6, 7, and 8 show the results of electromagnetic-field simulation. FIG. 6 shows a model used for the electromagnetic-field simulation. FIG. 7 is a cross-sectional view taken along a line VII-VII of FIG. 6. FIG. 8 is a diagram showing effects of the periodic structure part 59. In FIG. 8, a solid line indicates the result of a configuration having the partition wall 314 and the periodic structure part 59, and a broken line indicates the result of a configuration having the partition wall 314 without the periodic structure part 59. That is, the solid line indicates transmission characteristics of the configuration having the periodic structure part 59, and the broken line indicates transmission characteristics of the configuration having only the partition wall 314. FIG. 8 shows changes in the transmission amount in several-GHz bands relative to a configuration without the partition wall 314 and the periodic structure part 59.

As shown in FIG. 6, a dipole antenna is provided as a port P1 on the first surface 51a of the printed board 51, and a port P2 is provided at one end of the electronic device 10 in the Y direction. Further, the partition wall 314 and the periodic structure part 59 are provided between the port P1 and the port P2, and transmission characteristics from the port P1 toward the periodic structure part 59 are measured. As one example, a facing distance D1 between the partition wall 314 and the periodic structure part 59 (the printed board 51) shown in FIG. 7 is set to 0.1 mm, a width W1 that is a dimension of the partition wall 314 in the Y direction is set to 5 mm, and a protrusion height H1 of the partition wall 314 from the bottom wall 311 is set to 5 mm. The facing distance D1 is a facing distance between the land 57 in the surface layer on the first surface 51a side and the partition wall 314.

According to FIG. 8, it is clear that by providing the periodic structure part 59, the transmission amount can be reduced, that is, an attenuation amount can be increased, compared with a configuration in which only the partition wall 314 is provided. It is clear that propagation of electromagnetic noise to the external space can be suppressed more effectively than in a configuration in which space propagation is suppressed by the partition wall 314.

The internal space 30S is surrounded by an electromagnetic-wave shield body. The electromagnetic-wave shield body is constituted by the housing 30 including the partition wall 314, the ground layer 56, and the periodic structure part 59 including the ground layer 56. The electromagnetic-wave shield body suppresses, for example, propagation of electromagnetic noise generated by the electronic component 52 to the outside of the internal space 30S. In the electromagnetic-wave shield body, although the gap 33 exists between the partition wall 314 and the periodic structure part 59, propagation to the external space through the gap 33 can be suppressed.

### Summary of First Embodiment

According to the present embodiment, the printed board 51 is provided with the periodic structure part 59 including the ground layer 56, the plurality of lands 57, and the short-circuit portions 58. The periodic structure part 59 forms a mushroom structure, which is a type of metamaterial. The facing distance between the periodic structure part 59 and the metal member, which form the gap 33, is equal to or less than one quarter of a wavelength corresponding to the frequency of electromagnetic noise generated by the noise source mounted on the printed board 51. The periodic structure part 59 has high surface impedance with respect to the frequency of the electromagnetic noise. Therefore, even without using a gasket, it is possible to suppress propagation of electromagnetic noise to the external space through the gap 33. In other words, with a simple configuration, it is possible to suppress propagation of the electromagnetic noise to the external space. It is possible to suppress propagation of electromagnetic noise from the external space to the internal space 30S through the gap 33 and influence on the electronic component 52. In the illustrated electronic device 10, the case 31 including the partition wall 314 corresponds to the metal member, and the electronic component 52 corresponds to the noise source.

As illustrated, the metal member may be the housing 30 that accommodates the circuit board 50. The electromagnetic-wave shield body including the periodic structure part 59 can be constituted by the housing 30 and the elements of the printed board 51. With a simple configuration, propagation of the electromagnetic noise generated by the noise source to the external space can be suppressed.

According to the present embodiment, the printed board 51 is provided with the periodic structure part 59 including the ground layer 56, the plurality of lands 57, and the short-circuit portions 58. The periodic structure part 59 forms a mushroom structure, which is a type of metamaterial. The facing distance between the periodic structure part 59 and the metal member, which form the gap 33, has a length of greater than 0 mm and equal to or smaller than 12.5 mm. The periodic structure part 59 has high surface impedance at the frequency corresponding to the facing distance. Therefore, even without using a gasket, it is possible to suppress propagation of the electromagnetic noise of the frequency of equal to or less than 6 GHz to the external space through the gap 33. In other words, with a simple configuration, it is possible to suppress propagation of the electromagnetic noise to the external space. It is possible to suppress propagation of electromagnetic noise from the external space to the internal space 30S through the gap 33 and influence on the electronic component 52.

### Modification

Although an example in which the ground layer 56 is provided on the second surface 51b of the printed board 51 and the ground layer 56 is brought into contact with the cover 32 is illustrated above, the configuration is not limited thereto. There may be a gap between the ground layer 56 and the cover 32. The electromagnetic-wave shield body surrounding the noise source may be constituted by the case 31 including the partition wall 314, the ground layer 56, and the periodic structure part 59 including the ground layer 56.

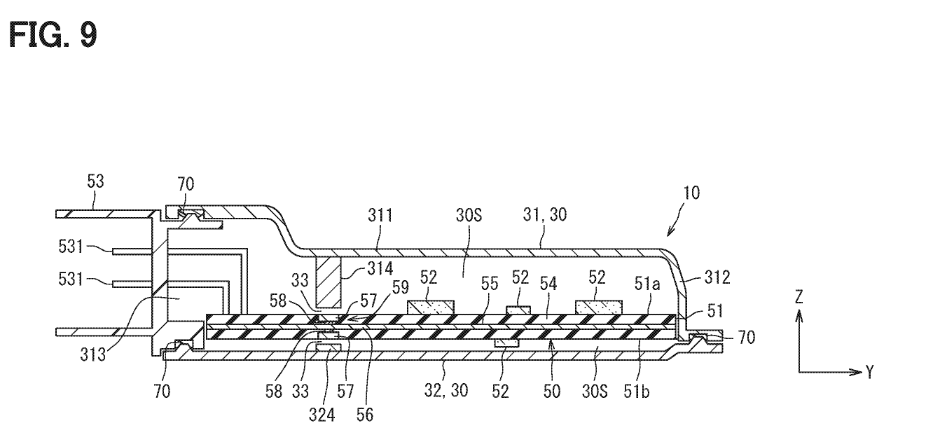

As shown in FIG. 9, the ground layer 56 may be disposed inside the insulating base material 54. The periodic structure part 59 may be disposed on both the first surface 51a side and the second surface 51b side. FIG. 9 corresponds to FIG. 2. With the periodic structure part 59 provided on the second surface 51b side, propagation of electromagnetic noise from the internal space 30S on the second surface 51b side to the external space may be suppressed. In FIG. 9, the electronic components 52 are disposed on the first surface 51a and the second surface 51b. The cover 32 forms a gap between the cover 32 and the second surface 51b of the printed board 51. The cover 32 includes a partition wall 324 protruding in the Z direction. By having the partition wall 324, the cover 32 forms the gap 33 allowing communication between the internal space 30S and the external space, between the circuit board 50 and the cover 32.

The lands 57 are disposed in the surface layer on the first surface 51a side and in the surface layer on the second surface 51b side. The lands 57 disposed in the surface layer on the second surface 51b side are arranged periodically along the gap 33 formed by the partition wall 324. The land 57 on the second surface 51b side is electrically connected to the ground layer 56 by the short-circuit portion 58. The periodic structure part 59 on the second surface 51b side also forms a mushroom structure in which the ground layer 56 and the land 57 facing each other are connected by the short-circuit portion 58. In the plan view, the periodic structure part 59 on the second surface 51b side may be disposed to overlap the periodic structure part 59 on the first surface 51a side, or may be disposed at a position shifted from the periodic structure part 59 on the first surface 51a side in the Y direction.

An example in which the case 31 having the partition wall 314 is used as the metal member forming the gap 33 is illustrated above. However, the configuration is not limited thereto. A position where the gap 33 is formed is not limited to the partition wall 314.

### Second Embodiment

A second embodiment is a modification based on a basic form of the preceding embodiment, and description of the preceding embodiment can be incorporated. In the preceding embodiment, the short-circuit portion 58 is connected to the center of the land 57. Alternatively, in order to increase a guided-wave distance (propagation distance), the short-circuit portion 58 may be connected to the land 57 at a position shifted from the center of the land 57.

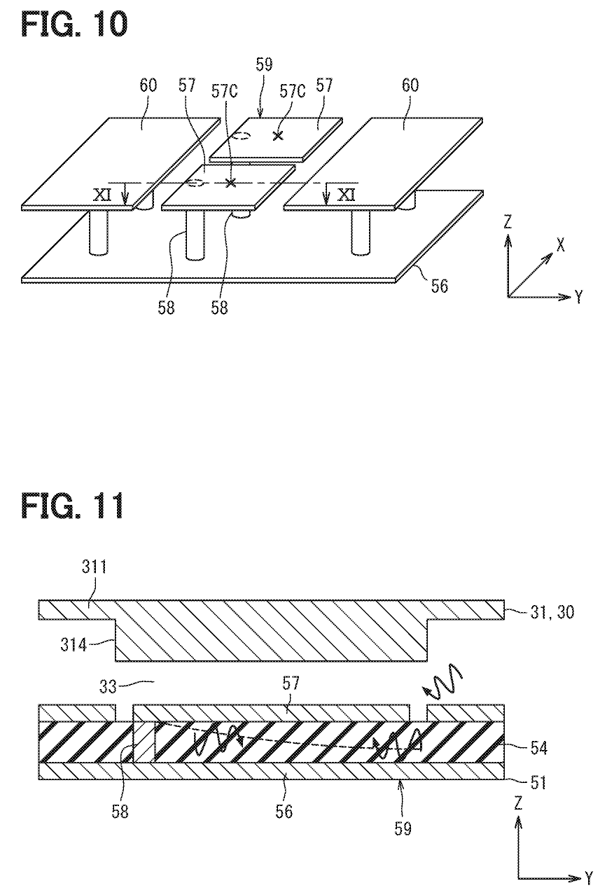

FIG. 10 is a perspective view showing the periodic structure part 59 in the electronic device according to the second embodiment. FIG. 10 corresponds to FIG. 5. In FIG. 10, for convenience, only the conductor of the printed board 51 is shown. In FIG. 10, a connection position of the short-circuit portion 58 on the land 57 is indicated by a broken line.

As shown in FIG. 10, the short-circuit portion 58 of the periodic structure part 59 is connected to the land 57 at a position shifted from a center 57C of the land 57 in the Y direction. The short-circuit portion 58 is connected to the land 57 at a position farther from the internal space 30S in the Y direction, that is, at a position shifted toward the external space side from the center 57C. The illustrated short-circuit portion 58 is connected to the land 57 such that an end of the short-circuit portion 58 in the Y direction coincides with an end of the land 57 on the external space side.

FIG. 11 is a cross-sectional view taken along a line XI-XI of FIG. 10. In FIG. 11, the case 31 including the partition wall 314 is also shown. The land 57 and the short-circuit portion 58 form an inverted L-shape structure. By shifting the short-circuit portion 58 from the center 57C, a guided-wave distance on an inner-layer side of the mushroom structure can be increased. Preferably, by connecting the short-circuit portion 58 to the end of the land 57 on the external space side, the guided-wave distance on the inner-layer side can be further increased. A guided-wave path on the inner-layer side functions as a stub with respect to a guided-wave path of the gap 33. The stub resonates at one quarter of a cell length, that is, a length of one side of the land 57. By shifting from the center 57C to the end on the external space side, the distance of the stub can be increased to nearly twice. Therefore, it is possible to suppress propagation of the electromagnetic noise of a lower frequency.

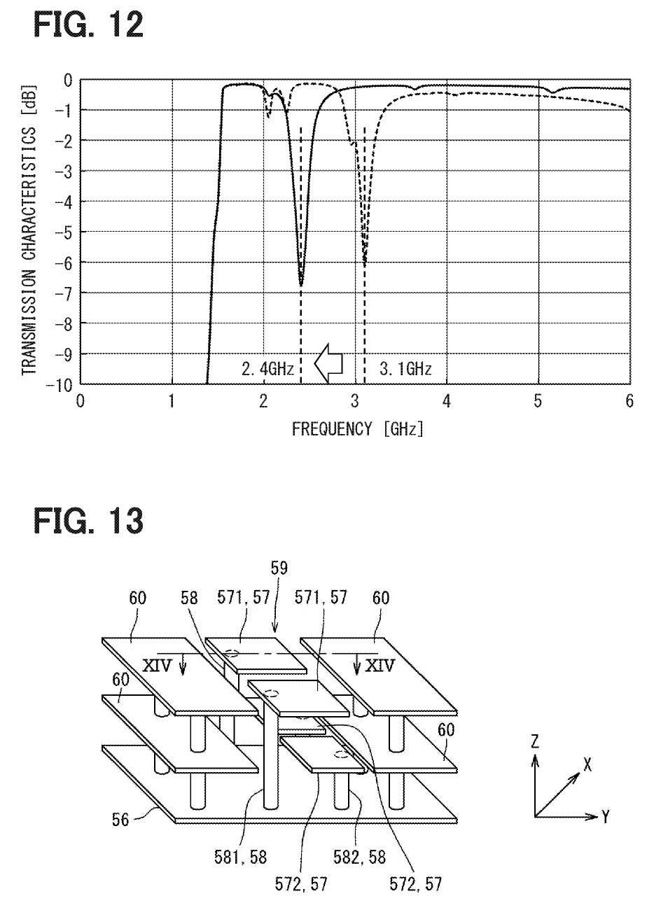

FIG. 12 is a diagram showing transmission characteristics (attenuation characteristics). FIG. 12 shows the results of electromagnetic-field simulation. A solid line indicates transmission characteristics when the short-circuit portion 58 is connected to the end of the land 57 on the external space side, and a broken line indicates transmission characteristics when the short-circuit portion 58 is connected to the center position of the land 57. An analysis model is the same as in FIG. 6. A cell pitch is set to 10 mm, a cell size is set to 9.8 mm, a facing distance between the partition wall 314 and the periodic structure part 59 is set to 0.3 mm, and a facing distance between the land 57 and the ground layer 56 is set to 45 μm.

As shown by the broken line, when the short-circuit portion 58 is connected to the center of the land 57, a resonance frequency is 3.1 GHz. As shown by the solid line, when the short-circuit portion 58 is connected to the end of the land 57 on the external space side, the resonance frequency is 2.4 GHz. According to FIG. 12, it is clear that by shifting the connection position of the short-circuit portion 58 from the center 57C toward the external space side, the resonance frequency can be lowered.

### Summary of Second Embodiment

As illustrated, the short-circuit portion 58 may be connected to the land 57 at a position shifted from the center 57C in the Y direction. Thus, compared with a configuration in which the short-circuit portion 58 is connected to the center 57C, propagation of the electromagnetic noise at a lower frequency can be suppressed. Propagation of the electromagnetic noise at a lower frequency can be suppressed while suppressing an increase in size.

The short-circuit portion 58 may be connected to the land 57 at a position between the end of the land 57 on the external space side and the center 57C. As illustrated, the short-circuit portion 58 may be connected to the end of the land 57 on the external space side. By connecting the short-circuit portion 58 to the end of the land 57 on the external space side, the guided-wave distance on the inner-layer side can be further increased, and propagation of the electromagnetic noise at a lower frequency can be suppressed.

### Modification

The direction to shift the short-circuit portion 58 from the center of the land 57 is not limited to the Y direction. The short-circuit portion 58 may be shifted in any direction that is orthogonal to the Z direction. For example, the short-circuit portion 58 may be connected to the land 57 at a position shifted from the center 57C of the land 57 in the X direction. The short-circuit portion 58 may be connected to an end of the land 57 in the X direction. Also in these cases, the guided-wave distance in the inner-layer side of the mushroom structure can be increased. Therefore, propagation of the electromagnetic noise at a lower frequency can be suppressed.

### Third Embodiment

A third embodiment is a modification based on a basic form of the preceding embodiment(s), and description of the preceding embodiment(s) can be incorporated. In the preceding embodiment, the guided-wave distance on the inner-layer side is increased by connecting the short-circuit portion 58 to the land 57 at a position shifted from the center 57C of the land 57. Alternatively or additionally, the guided-wave distance on the inner-layer side may be increased by arranging the lands 57 in multiple stages.

FIG. 13 is a perspective view showing the periodic structure part 59 of the electronic device according to the third embodiment. FIG. 13 corresponds to FIG. 10. In FIG. 13, for convenience, only the conductor of the printed board 51 is shown. In FIG. 13, the connection position of the short-circuit portion 58 to the land 57 is indicated by a broken line.

As shown in FIG. 13, the lands 57 of the periodic structure part 59 are arranged in multiple stages or levels in the Z direction. The number of stages is not particularly limited, and may be two, three or more. The illustrated lands 57 are arranged in two stages. The land 57 of each cell includes a first land 571 and a second land 572. The second land 572 is interposed between the first land 571 and the ground layer 56. The entire length of the second land 572 overlaps the first land 571 in the plan view. When the first land 571 is referred to as a first-layer conductor, the second land 572 is disposed in a second layer, and the ground layer 56 is disposed in a third layer. The first land 571 is a first-stage (uppermost) land, and the second land 572 is a second-stage land.

Also in the present embodiment, the short-circuit portion 58 is connected to the land 57 at a position shifted from the center 57C in the Y direction so that a propagation distance on the inner-layer side becomes long. The illustrated short-circuit portion 58 is connected to the land 57 at a position shifted from the center 57C in the Y direction. The short-circuit portion 58 includes a first short-circuit portion 581 connected to the first land 571 and a second short-circuit portion 582 connected to the second land 572. The first short-circuit portion 581 is connected to the first land 571 at a position shifted toward the external space side from the center 57C in the Y direction. The second short-circuit portion 582 is connected to the second land 572 at a position shifted toward the internal space 30S side relative to the center 57C in the Y direction. The illustrated first short-circuit portion 581 is connected to the first land 571 such that an end of the first short-circuit portion 581 in the Y direction coincides with an end of the first land 571 on the external space side. The second short-circuit portion 582 is connected to the second land 572 such that an end of the second short-circuit portion 582 in the Y direction coincides with an end of the second land 572 on the internal space 30S side.

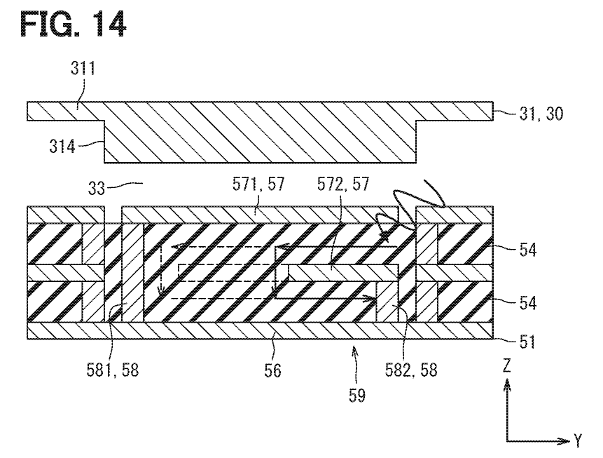

FIG. 14 is a cross-sectional view taken along a line XIV-XIV of FIG. 13. In FIG. 14, the case 31 including the partition wall 314 is also shown. By providing the second land 572, that is, the lower-stage land 57, guided-wave paths on the inner-layer side functioning as the stubs also become multiple stages, and the guided-wave distance can be further increased. That is, propagation of the electromagnetic noise at a lower frequency can be suppressed. Also, as shown in FIG. 14, the guided-wave distance can be adjusted by adjusting the length of the lower-stage land 57. For example, the longer the length of the second land 572 in the Y direction is, the longer the guided-wave distance can be.

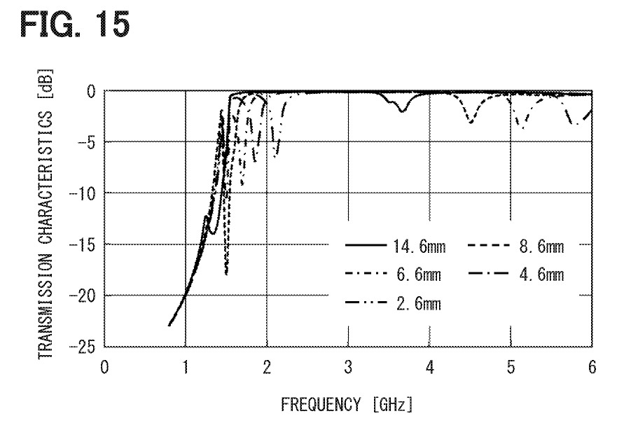

FIG. 15 is a diagram showing transmission characteristics (attenuation characteristics). FIG. 15 shows the results of electromagnetic-field simulation. FIG. 15 shows five levels of the guided-wave distance on the inner-layer side. The five levels of the guided-wave distance are 14.6 mm (solid line), 8.6 mm (broken line), 6.6 mm (short dash-dot line), 4.6 mm (long dash-dot line), and 2.6 mm (two-dot chain line). The analysis model is the same as in FIG. 12. However, a facing distance between the first land 571 and the second land 572 is set to 45 μm, and a facing distance between the second land 572 and the ground layer 56 is set to 45 μm.

As shown in FIG. 15, it is clear that the longer the guided-wave distance is, that is, the longer the length of the lower-stage land 57 is, the lower the resonance frequency can be. For example, the guided-wave distance can be made about twice the cell length, and it is possible to lower the frequency level to around 1.2 GHz.

### Summary of Third Embodiment

As illustrated, the land 57 may include the first land 571 and the second land 572. By arranging the lands 57 in multiple stages, propagation of the electromagnetic noise at a lower frequency can be suppressed compared with a single-stage arrangement of the land 57. Propagation of the electromagnetic noise at a lower frequency can be suppressed while suppressing an increase in size.

While arranging the lands 57 in multiple stages, the short-circuit portions 58 may be connected to the lands 57 at the positions shifted from the respective centers 57C in the Y direction. The first short-circuit portion 581 may be connected to the first land 571 at a position shifted toward the external space side from the center 57C, and the second short-circuit portion 582 may be connected to the second land 572 at a position shifted toward the internal space 30S side from the center 57C. That is, the short-circuit portion 58 corresponding to an odd-numbered-stage land 57 may be connected to the land 57 at a position shifted toward the external space side from the center 57C, and the short-circuit portion 58 corresponding to an even-numbered-stage land 57 may be connected to the land 57 at a position shifted toward the internal space 30S side from the center 57C. Thus, propagation of the electromagnetic noise at a lower frequency can be suppressed compared with a configuration in which the short-circuit portion 58 is connected to the land 57 at a position shifted from the center 57C without multi-stage arrangement.

### Modification

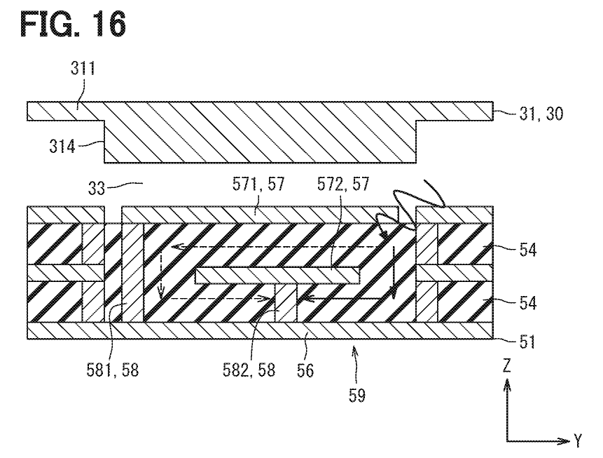

A connection position of the second short-circuit portion 582 is not limited to the end of the second land 572 on the internal space 30S side. As shown in FIG. 16, the second short-circuit portion 582 may be connected to the second land 572 at a position away from the end of the second land 572. FIG. 16 corresponds to FIG. 14. According to this, two inner-layer guided-wave paths having different guided-wave distances are formed. Therefore, while lowering the frequency, propagation of the electromagnetic noise at a plurality of frequencies can be effectively suppressed.

As described in the preceding embodiment, the direction to shift the short-circuit portion 58 from the center 57C of the land 57 is not limited to the Y direction.

### Fourth Embodiment

A fourth embodiment is a modification based on a basic form of the preceding embodiment(s), and description of the preceding embodiment(s) can be incorporated. In the preceding embodiment(s), the housing 30 includes the case 31 and the cover 32. Alternatively, the housing 30 may include a base and covers disposed on both sides of the base. The base may have a through hole. The electronic device may include a plurality of circuit boards 50, and the plurality of circuit boards 50 may be electrically connected through the through hole.

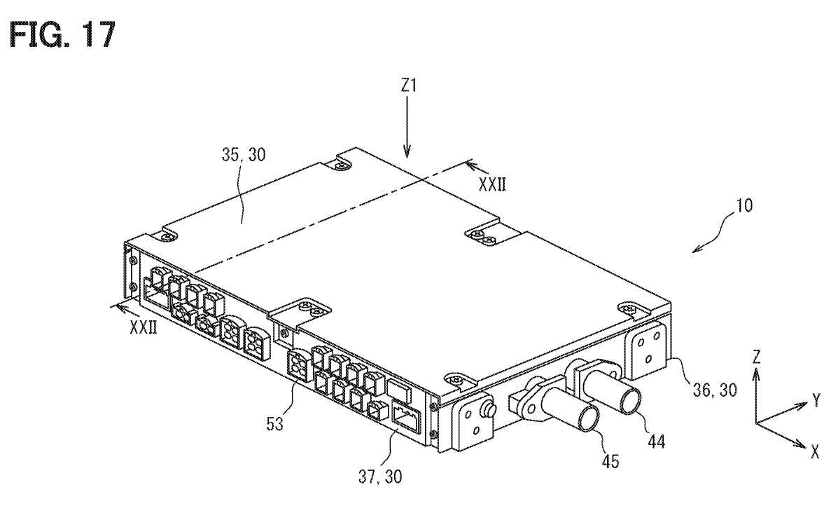

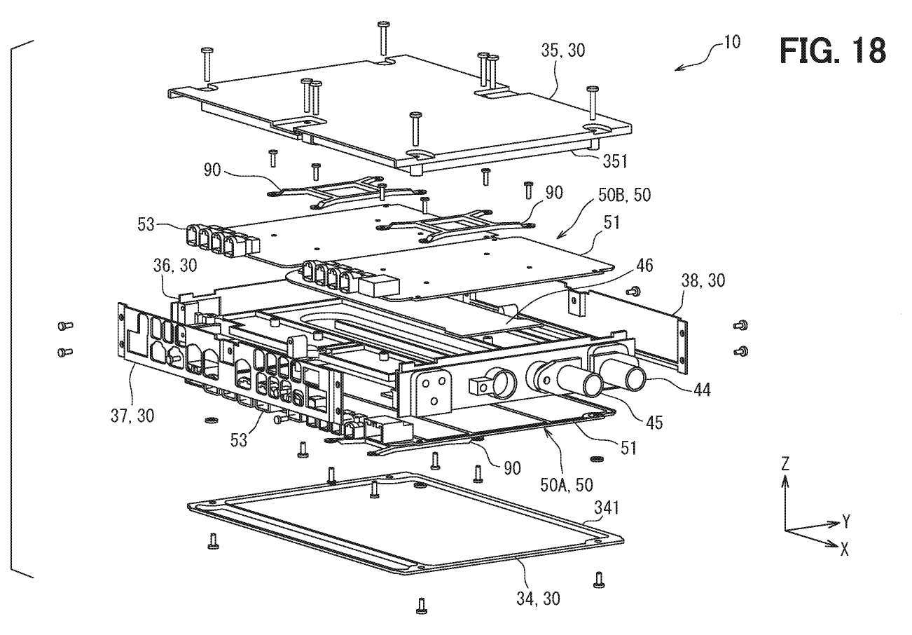

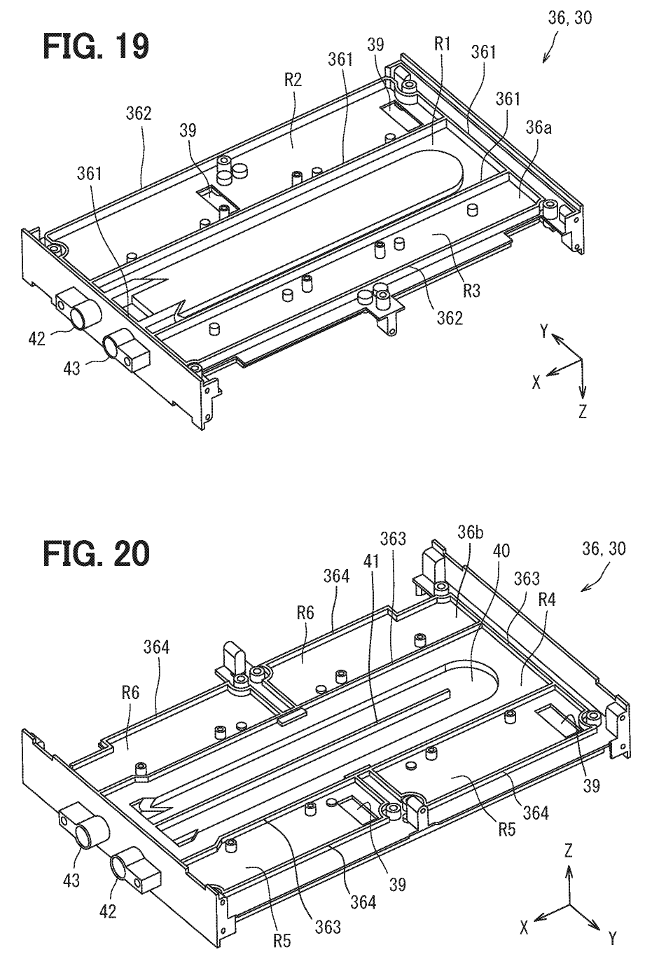

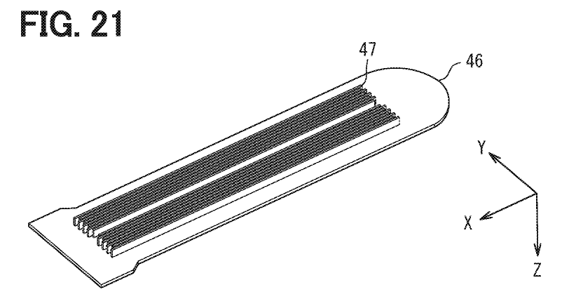

FIG. 17 is a perspective view showing an example of the electronic device according to the fourth embodiment. FIG. 18 is an exploded perspective view of the electronic device. For convenience, in FIG. 18, illustrations of electronic component and heat conductive member are omitted. FIG. 19 is a perspective view showing one surface side of the base. FIG. 20 is a perspective view showing a back surface side of the base. FIG. 21 is a perspective view showing a flow-channel cover.

The illustrated electronic device 10 includes the housing 30, the circuit board 50, and a back plate 90. The housing 30 includes covers 34, 35, a base 36, and side plates 37, 38. The cover 34 and the cover 35 define an outer contour of the electronic device 10 in the Z direction. The base 36 is disposed between the cover 34 and the cover 35 in the Z direction. Both ends of the base 36 in the X direction define the outer contour of the electronic device 10. The side plate 37 and the side plate 38 define the outer contour of the electronic device 10 in the Y direction. The side plate 37 has an opening for exposing the connector 53 to the outside. The illustrated covers 34, 35 and side plates 37, 38 are fixed to the base 36 by screw fastening.

The cover 34 has the partition wall 341 on a surface facing the base 36. The partition wall 341 protrudes in the Z direction relative to other portions of the cover 34. The partition wall 341 is provided near an outer peripheral edge of the cover 34 and has a ring shape in the plan view. The cover 35 has a partition wall 351 on a surface facing the base 36. The partition wall 351 is provided corresponding to two circuit boards 50B described later. Each of the partition walls 351 has a ring shape in the plan view.

The base 36 has a first surface 36a and a second surface 36b. The second surface 36b is a back surface opposite the first surface 36a in the Z direction. A circuit board 50A is disposed on the first surface 36a of the base 36, and a circuit board 50B is disposed on the second surface 36b. The base 36 is formed with a through hole 39 opening to the first surface 36a and the second surface 36b. The circuit board 50A and the circuit boards 50B are electrically connected via the through hole 39. The base 36 has two through holes 39 corresponding to the two circuit boards 50B.

The base 36 has a function of cooling the circuit board 50. The illustrated base 36 has a flow channel 40. The flow channel 40 is disposed so as to effectively cool the circuit boards 50A, 50B, particularly, the heat-generating component, and is thus disposed so as to overlap at least the heat-generating component in the plan view. The flow channel 40 extends along an arrangement direction of the two circuit boards 50B, that is, in the X direction. The flow channel 40 is disposed so as to overlap, in the plan view, the heat-generating component on the circuit board 50A and the heat-generating components on the two circuit boards 50B. The flow channel 40 is disposed in a region R4 on the second surface 36b. The flow channel 40 is provided to be recessed toward the first surface 36a side.

The flow channel 40 has a folded-back structure. The flow channel 40 is separated by a partition wall 41 extending in the X direction and has a substantially U-shape in the plan view. At one end of the base 36 in the X direction, an inlet 42 and an outlet 43 for refrigerant are provided. The inlet 42 is connected to one end of the flow channel 40 having the folded-back structure, and the outlet 43 is connected to the other end of the flow channel 40. As the refrigerant, for example, a phase-change refrigerant such as water or ammonia, or a non-phase-change refrigerant such as an ethylene glycol-based refrigerant can be used.

The base 36 has an inlet pipe 44 and an outlet pipe 45. The inlet pipe 44 is attached to the inlet 42. The outlet pipe 45 is attached to the outlet 43. The inlet pipe 44 is a pipe for supplying the refrigerant to the flow channel 40. The outlet pipe 45 is a pipe for discharging the refrigerant from the flow channel 40. Attachment positions of the inlet pipe 44 and the outlet pipe 45 are not particularly limited. The illustrated inlet pipe 44 and the illustrated outlet pipe 45 are attached to a same face.

The base 36 has a flow-channel cover 46. The flow-channel cover 46 is a member that covers the flow channel 40. A peripheral portion of the flow-channel cover 46 is joined in a liquid-tight manner to a peripheral portion around the flow channel 40 in the base 36. As illustrated, the flow-channel cover 46 may have a plurality of fins 47 on a surface on the flow channel 40 side.

The base 36 has partition walls 361, 362, 363, 364. The partition wall 361 and the partition wall 362 are provided on the first surface 36a of the base 36. The partition wall 361 and the partition wall 362 protrude in the Z direction from the first surface 36a. The partition wall 361 is provided so as to surround the flow channel 40 in the plan view. The partition wall 361 provides a region R1. The partition wall 362 is connected to the partition wall 361. The partition wall 362 is disposed so as to interpose the partition wall 361 in the Y direction. The base 36 has two partition walls 362. One of the two partition walls 362 provides a region R2 together with the partition wall 361, and the other partition wall 362 provides a region R3 together with the partition wall 361. The region R2 and the region R3 are each surrounded by the partition wall 361 and the partition wall 362. In the Y direction, the region R1 is located between the region R2 and the region R3. A part of the partition wall 361 and the partition wall 362 are disposed near an outer peripheral edge of the base 36.

The partition wall 363 and the partition wall 364 are provided on the second surface 36b of the base 36. The partition wall 363 and the partition wall 364 protrude in the Z direction from the second surface 36b. The partition wall 363 is provided so as to surround the flow channel 40 in the plan view. The partition wall 363 provides the region R4. The partition wall 364 is connected to the partition wall 363. The partition wall 364 is disposed so as to interpose the partition wall 363 in the Y direction. The base 36 has four partition walls 364. Two partition walls 364 are provided on each side in the Y direction. On each side in the Y direction, the two partition walls 364 are arranged in the X direction corresponding to the two circuit boards 50B. Two of the four partition walls 364 provide regions R5 together with the partition wall 363, and the other two partition walls 364 provide regions R6 together with the partition wall 363. The two regions R5 are arranged in the X direction. The two regions R6 are arranged in the X direction. In the Y direction, the region R4 is located between the region R5 and the region R6. A part of the partition wall 363 and the partition wall 364 are provided near an outer peripheral edge of the base 36.

The through hole 39 is disposed in the region R2 on the first surface 36a and in the region R5 on the second surface 36b. The flow channel 40 is disposed in the region R4 on the second surface 36b. The flow channel 40 is located in the region R1 on the first surface 36a.

The circuit board 50 includes the circuit board 50A and the circuit board 50B as described above. The circuit board 50A and the circuit board 50B are disposed so as to sandwich the base 36 in the Z direction. In the illustrated electronic device 10, the circuit board 50A is a base board and the circuit board 50B is an expansion board. The circuit board 50A is a board on which common functions that are not changed depending on vehicle type or specifications are mounted. The circuit board 50B is a board for expanding functions relative to the base board. The circuit board 50B is a board on which additional functions depending on vehicle type or specifications are mounted. The circuit board 50B is replaceable depending on vehicle type or specifications.

For example, the circuit board 50A has a primary power supply system, an IVI function, and the like mounted thereon. IVI is an abbreviation for In-Vehicle Infotainment. The circuit board 50B has an AD function or an ADAS function mounted thereon. AD is an abbreviation for Autonomous Driving system. ADAS is an abbreviation for Advanced Driving Assistant System. The electronic device 10 includes one circuit board 50A and two circuit boards 50B.

Among the electronic components 52 constituting the circuit board 50A, a component that generates noise and/or a component affected by noise is mounted in the region R1. Noise becomes a problem particularly as the operating frequency increases. In the region R1, the heat-generating component that generates heat by operation is mounted as the electronic component 52. The electronic component 52 mounted in the region R1 includes, for example, an SoC. SoC is an abbreviation for System on Chip. At least one of the heat-generating components disposed in the region R1 is connected to the base 36 via a heat conductive member 91, such as a TIM. TIM is an abbreviation for Thermal Interface Material.

Among the electronic components 52 constituting the circuit board 50A, a communication IC for high-speed data communication between the circuit board 50A and the circuit board 50B, a communication IC for communication with a device (external device) different from the electronic device 10, and the like are mounted in the region R2.

The circuit board 50B has a configuration similar to the circuit board 50A. The two circuit boards 50B are disposed side-by-side in the X direction. Each of the circuit boards 50B has about one-half the size of the circuit board 50A in the plan view.

On the circuit board 50A, a connector 61 is mounted separately from the connector 53. On the circuit board 50B, a connector 62 is mounted separately from the connector 53. By connecting the connector 61 and the connector 62 through the through hole 39, the circuit board 50A and the circuit board 50B are connected to be communicable. The connector 61 and the connector 62 may be referred to as a board-to-board connector. Instead of the connector 61 and the connector 62, a flat wire or a flexible board may be used.

The circuit board 50A and the circuit board 50B have the periodic structure parts 59. The periodic structure part 59 will be described later.

The back plate 90 presses the circuit board 50 against the base 36. The back plate 90 has spring properties and presses the circuit board 50 against the base 36 by a reaction force due to spring deformation. The back plate 90 is disposed on a back surface of the circuit board 50 opposite to a surface facing the base 36, that is, on a back side of the circuit board 50 opposite to the base 36. The illustrated electronic device 10 includes three back plates 90. One of the three back plates 90 is disposed on the back side of the circuit board 50A. The back plate 90 presses the electronic component 52 located in the region R1 against the base 36. The remaining two back plates 90 are disposed on the back sides of the circuit boards 50B. The back plates 90 press the electronic components 52 located in the regions R4 against the base 36.

### Periodic Structure Part

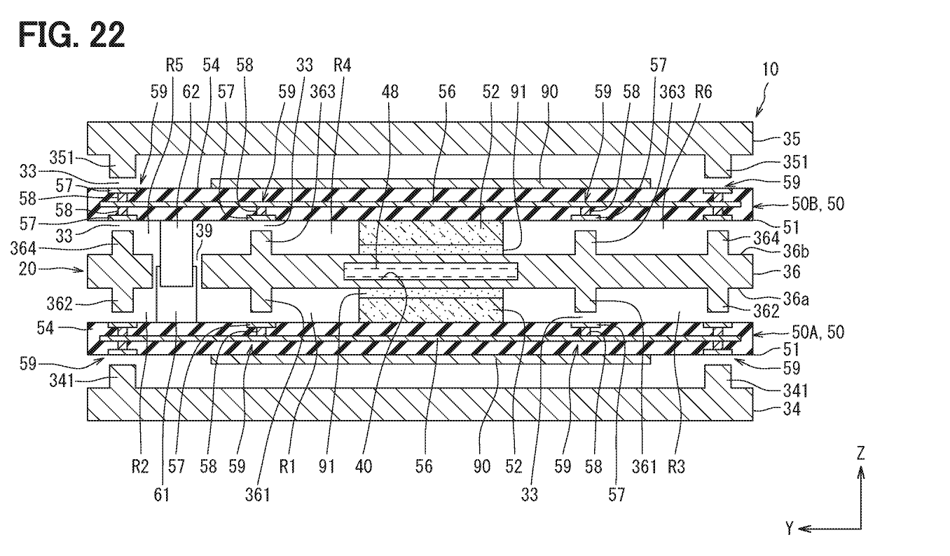

FIG. 22 is a cross-sectional view taken along line XXII-XXII of FIG. 17. Reference sign 48 denotes the refrigerant flowing through the flow channel 40. In FIG. 22, for convenience, among conductors of the printed board, only conductors constituting the periodic structure part are shown. As shown in FIG. 22, the circuit board 50 (the printed board 51) of the present embodiment also has the periodic structure part 59. The periodic structure part 59 includes the ground layer 56, the plurality of lands 57, and the short-circuit portion 58 as described above.

In the illustrated electronic device 10, the ground layer 56 is disposed inside the insulating base material 54. The circuit board 50A has the periodic structure parts 59 in a portion facing the partition wall 341 of the cover 34 and in portions facing the partition wall 361 and the partition wall 362 of the base 36. The circuit board 50B has the periodic structure part 59 in a portion facing the partition wall 351 of the cover 35 and in portions facing the partition wall 363 and the partition wall 364 of the base 36.

The periodic structure parts 59 form the gaps 33 with the corresponding partition walls 341, 351, 361, 362, 363, 364. In each of the periodic structure parts 59, the plurality of lands 57 are arranged periodically along the gap 33. The plurality of lands 57 are provided periodically along the corresponding partition walls 341, 351, 361, 362, 363, 364. The plurality of lands 57, that is, the periodic structure parts 59 are provided so as to surround the electronic component 52 serving as the noise source in the plan view. The facing distance between the periodic structure part 59 and the corresponding one of the partition walls 341, 351, 361, 362, 363, 364 is equal to or less than one quarter of a wavelength corresponding to an operating frequency of the electronic component 52 serving as the noise source.

### Summary of Fourth Embodiment

As illustrated, the circuit board 50A disposed on the first surface 36a side of the base 36 and the circuit board 50B disposed on the second surface 36b side may be electrically connected by the connector 61 and the connector 62 via the through hole 39 of the base 36. The base 36 corresponds to the metal member. The circuit board 50A corresponds to a first circuit board, and the circuit board 50B corresponds to a second circuit board. The connector 61 and the connector 62 correspond to a connecting portion. In this state, at least one of the circuit board 50A and the circuit board 50B may be provided with the periodic structure part 59. The ground layer 56 of the periodic structure part 59 is provided so as to enclose the noise source (the electronic component 52) in the plan view in the thickness direction of the printed board 51. The lands 57 and the short-circuit portions 58 are provided so as to surround the noise source in the plan view. The through hole 39 is provided in a region outside the plurality of lands 57 surrounding the noise source in the plan view.

The lands 57 of the periodic structure part 59 corresponding to the partition wall 361 are provided so as to surround the electronic component 52 of the circuit board 50A disposed in the region R1 in the plan view. Therefore, for example, it is possible to suppress electromagnetic noise generated by the electronic component 52 of the circuit board 50A from acting on the electronic component 52 of the circuit board 50B through the gap 33 formed by the partition wall 361 and the through hole 39. For example, it is possible to suppress electromagnetic noise generated by the electronic component 52 of the circuit board 50B from acting on the electronic component 52 of the circuit board 50A through the through hole 39 and the gap 33 formed by the partition wall 361.

The lands 57 of the periodic structure part 59 corresponding to the partition wall 362 are provided so as to surround the electronic components 52 of the circuit board 50A disposed in the region R1, the region R2, and the region R3 in the plan view. Therefore, for example, it is possible to suppress electromagnetic noise generated by the electronic components 52 of the circuit board 50A from propagating to the outside of the housing 30. The lands 57 of the periodic structure part 59 corresponding to the partition wall 341 are provided so as to surround the electronic components 52 of the circuit board 50A disposed in the region R1, the region R2, and the region R3 in the plan view. Therefore, for example, it is possible to suppress electromagnetic noise generated by the electronic components 52 of the circuit board 50A from propagating to the outside of the housing 30.

As illustrated, each of the circuit boards 50A, 50B may have the periodic structure part 59. The lands 57 of the periodic structure part 59 corresponding to the partition wall 363 are provided so as to surround the electronic component 52 of the circuit board 50B disposed in the region R4 in the plan view. Therefore, for example, it is possible to suppress electromagnetic noise generated by the electronic component 52 of the circuit board 50B from acting on the electronic component 52 of the circuit board 50A through the gap 33 formed by the partition wall 363 and the through hole 39. For example, it is possible to suppress electromagnetic noise generated by the electronic component 52 of the circuit board 50A from acting on the electronic component 52 of the circuit board 50B through the through hole 39 and the gap 33 formed by the partition wall 363.

The lands 57 of the periodic structure part 59 corresponding to the partition wall 364 are provided so as to surround the electronic components 52 of the circuit board 50B disposed in the region R4, the region R5, and the region R6 in the plan view. Therefore, for example, it is possible to suppress electromagnetic noise generated by the electronic components 52 of the circuit board 50B from propagating to the outside of the housing 30. The lands 57 of the periodic structure part 59 corresponding to the partition wall 351 are provided so as to surround the electronic components 52 of the circuit board 50B disposed in the region R4, the region R5, and the region R6 in the plan view. Therefore, for example, it is possible to suppress electromagnetic noise generated by the electronic components 52 of the circuit board 50B from propagating to the outside of the housing 30.

As illustrated, the metal member may be the housing 30 that accommodates the circuit board. The electromagnetic-wave shield body including the periodic structure part 59 can be formed by the housing 30 and the elements of the printed board 51. It is possible to suppress propagation of electromagnetic noise generated by the noise source to the external space, with a simple configuration.

### Modification

An example in which the periodic structure parts 59 are provided in portions of the circuit board 50 facing the partition walls 341, 351, 361, 362, 363, 364 is described above. However, the configuration is not limited thereto. The periodic structure part 59 may be provided to face a part of the partition walls 341, 351, 361, 362, 363, 364. For example, the periodic structure part 59 may be provided only in the portion of the circuit board 50A facing the partition wall 361. The periodic structure part 59 may be provided only in the portion of the circuit board 50B facing the partition wall 363. The periodic structure parts 59 may be provided only in portions of the circuit board 50A facing the partition walls 361, 362 disposed near the outer peripheral edge of the base 36 and portions of the circuit board 50B facing the partition walls 363, 364 disposed near the outer peripheral edge of the base 36.

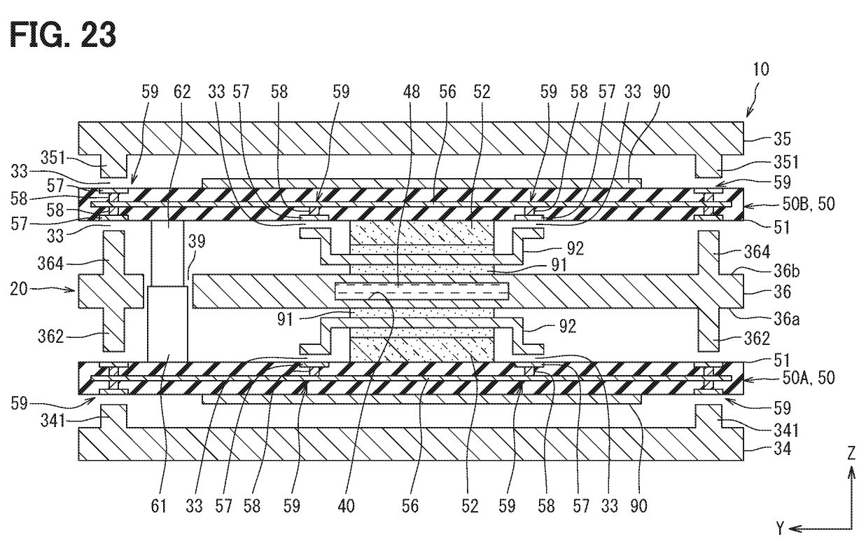

The metal member is not limited to the housing 30. For example, as shown in FIG. 23, the electronic device 10 may include a shield cover 92. FIG. 23 corresponds to FIG. 22. The shield cover 92 is provided separately from the housing 30. The shield cover 92 is disposed between the circuit board 50 and the base 36. The shield cover 92 is disposed so as to cover the noise source, for example the electronic component 52, and to form a ring-shaped gap 33 surrounding the noise source between the shield cover 92 and the circuit board 50. The periodic structure part 59 faces an outer peripheral edge of the shield cover 92 via the gap 33. The plurality of lands 57 are provided periodically along the gap 33. The plurality of lands 57 surround the noise source in the plan view. The shield cover 92 corresponds to the metal member that forms the gap 33 between the shield cover 92 and the periodic structure part 59.

### Fifth Embodiment

A fifth embodiment is a modification based on a basic form of the preceding embodiment(s), and description of the preceding embodiment(s) can be incorporated. In the preceding embodiment(s), the structure part having the mushroom structure has the plurality of lands. As another example, the structure part may have a single land.

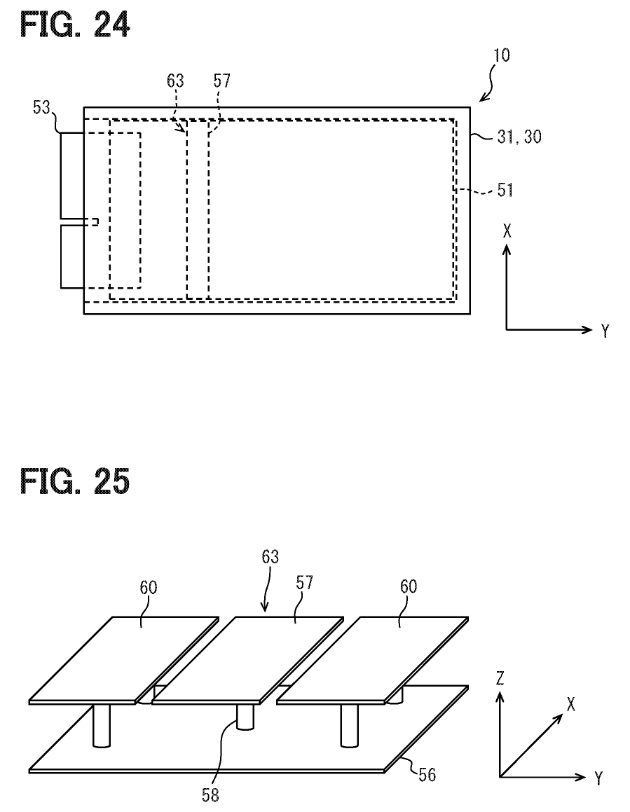

FIG. 24 is a plan view of an example of an electronic device according to the present embodiment. FIG. 24 corresponds to FIG. 3. FIG. 25 is a perspective view of a structure part. FIG. 25 corresponds to FIG. 5. Similar to the preceding embodiment (see FIGS. 1 - 3), the case 31 constituting the housing 30 has the partition wall 314 (not shown). The printed board 51 has a structure part 63, as the structure part forming the mushroom structure. The structure part 63 includes the ground layer 56, the land 57, and the short-circuit portion 58. Different from the periodic structure part 59, the structure part 63 has only one land 57. The land 57 extends along the gap 33. The land 57 extends along the partition wall 314 (not shown). The illustrated land 57 extends from one end of the printed board 51 to the other end of the printed board 51 in the X direction. The land 57 faces the partition wall 314 over the substantially entire length of the partition wall 314.

As described above, the number of the via conductors forming the short-circuit portion 58 is not particularly limited, as described above. For example, the short-circuit portion 58 may be constituted by a single via conductor, or a plurality of via conductors. The connecting position of the short-circuit portion 58 to the land 57 may be the central position of the land 57, or a position shifted from the center of the land 57 in a direction orthogonal to the Z direction. The structure part 63 may have a single first land 571 at the surface layer on the first surface 51a side, and a single second land 572. For example, the first land 571 extends along the gap 33.

### Summary of Fifth Embodiment

According to the present embodiment, the printed board 51 is provided with the structure part 63 including the ground layer 56, the land 57, and the short-circuit portion 58. The structure part 63 has the mushroom structure, as a type of metamaterial. The facing distance between the structure part 63 and the metal member has the length of equal to or less than one fourth of the wavelength corresponding to the frequency of the electromagnetic noise generated by the noise source mounted on the printed board 51. The structure part 63 has the high surface impedance with respect to the frequency of the electromagnetic noise. Therefore, even without using a gasket, it is possible to suppress propagation of the electromagnetic noise to the external space through the gap 33. That is, it is possible to suppress propagation of the electromagnetic noise to the external space with a simple configuration. It is possible to suppress propagation of electromagnetic noise from the external space to the internal space 30S through the gap 33 and to affect the electronic components 52. In the illustrated electronic device 10, the case 31 corresponds to the metal member and the electronic component 52 corresponds to the noise source.

Similarly to the preceding embodiment, the facing distance may be set to be greater than 0 mm and equal to or smaller than 12.5 mm. In this case, the electromagnetic wave at the frequency of 6 GHz or less can be blocked. For example, the electromagnetic noise in several-GHz bands (1 to 6 GHz) can be blocked.

### Modification

It has been illustrated an example in which the land 57 is disposed to face the partition wall 314 substantially over the entire length of the partition wall 314 in the configuration in which the housing 30 includes the case 31 and the cover 32. However, the configuration is not limited thereto. In a configuration in which the housing 30 includes the covers 34, 35, the base 36, and the side plates 37, 38 (see FIGS. 17 - 22), the configuration of the land 57 shown in FIGS. 24 and 25 may be employed. In the configuration of having the shield cover 92, the configuration of the land 57 shown in FIGS. 24 and 25 may be employed.

### Other Embodiments

The disclosure in this specification and the drawings is not limited to the illustrated embodiments. The disclosure includes the illustrated embodiments and modifications thereof made by those skilled in the art. For example, the disclosure is not limited to combinations of components and/or elements shown in the embodiments. The disclosure can be implemented with various combinations. The disclosure can have additional portions that can be added to the embodiments. The disclosure includes embodiments in which components and/or elements of the embodiments are omitted. The disclosure includes replacement or combination of components and/or elements between one embodiment and another embodiment. The disclosed technical scope is not limited by the description of the embodiments. Some disclosed technical scopes are indicated by the claims and should be construed to include all modifications within the meaning and scope equivalent to the claims.

The disclosure in this specification and the drawings is not limited by the claims. The disclosure in this specification and the drawings includes technical ideas described in the claims and extends to various and broader technical ideas than the technical ideas described in the claims. Therefore, various technical ideas can be extracted from the disclosure of this specification and the drawings without being bound by the claims.

When an element or a layer is referred to as being “on,” “coupled to,” “connected to,” or “joined to” another element or layer, it may be directly on, coupled to, connected to, or joined to the other element or layer, or intervening elements or intervening layers may be present. In contrast, when an element is referred to as being “directly on,” “directly coupled to,” “directly connected to,” or “directly joined to” another element or layer, no intervening element or intervening layer is present. Other terms used to describe relationships between elements should be interpreted in a similar manner (e.g., “between” versus “directly between,” “adjacent” versus “directly adjacent”). As used herein, the term “and/or” includes any and all combinations of one or more of the associated listed items. That is, “A and/or B” means at least one of A and B.

Spatially relative terms such as “inner,” “outer,” “back,” “below,” “lower,” “above,” “upper,” and the like are used herein for ease of description to describe the relationship of one element or feature to another element or feature as illustrated. Spatially relative terms can be intended to encompass different orientations of the device in use or operation in addition to the orientation depicted in the drawings. For example, if the device in the drawings is turned over, elements described as “below” or “directly below” other elements or features would then be oriented “above” the other elements or features. Thus, the term “below” can encompass both above and below orientations. The device may be otherwise oriented (rotated 90 degrees or in other orientations), and the spatially relative descriptors used herein are interpreted accordingly.

What is claimed is:

1. An electronic device comprising:
a circuit board including a printed board and a noise source mounted on the printed board; and
a metal member providing an internal space accommodating the noise source and defining, between the metal member and the circuit board, a gap connecting the internal space to an external space,
wherein
the printed board includes a periodic structure part including:
a ground layer providing a ground potential;
a plurality of lands disposed to face the ground layer and disposed periodically along the gap; and
a plurality of short-circuit portions electrically connecting the plurality of lands to the ground layer, and
a facing distance between the periodic structure part and the metal member at the gap is equal to or less than one quarter of a wavelength corresponding to a frequency of electromagnetic noise generated by the noise source.

2. The electronic device according to claim 1, wherein
each of the short-circuit portions is connected to a corresponding land at a position shifted from a center of the corresponding land.

3. The electronic device according to claim 2, wherein
each of the short-circuit portions is connected to the corresponding land at a position shifted from the center of the corresponding land toward the external space.

4. The electronic device according to claim 1, wherein
each of the lands includes a first land and a second land interposed between the first land and the ground layer.

5. The electronic device according to claim 4, wherein:
the short-circuit portions include a first short-circuit portion corresponding to the first land and a second short-circuit portion corresponding to the second land;
the first short-circuit portion is connected to the first land at a position shifted from a center of the first land toward the external space; and
the second short-circuit portion is connected to the second land at a position shifted from a center of the second land toward the internal space.

6. The electronic device according to claim 4, wherein:
the short-circuit portions include a first short-circuit portion corresponding to the first land and a second short-circuit portion corresponding to the second land; and
the second short-circuit portion is connected to the second land at a position spaced from an end of the second land in a direction orthogonal to both a direction in which the plurality of lands are arranged and a thickness direction of the printed board.

7. The electronic device according to claim 1, wherein:
the metal member has a first surface, a second surface opposite the first surface, and a through hole opening on the first surface and the second surface;
the circuit board includes a first circuit board disposed adjacent to the first surface of the metal member and a second circuit board adjacent to the second surface;
the electronic device further comprises a connecting portion electrically connecting the first circuit board and the second circuit board through the through hole;
at least one of the first circuit board and the second circuit board includes the periodic structure part;
the ground layer is disposed so as to enclose the noise source in a plan view of the printed board in a thickness direction;
the lands and the short-circuit portions are disposed so as to surround the noise source in the plan view; and
the through hole is located outside the lands surrounding the noise source in the plan view.

8. The electronic device according to claim 7, wherein
each of the first circuit board and the second circuit board includes the periodic structure part.

9. The electronic device according to claim 1, wherein
the metal member is a housing accommodating the circuit board therein.

10. The electronic device according to claim 1, further comprising:
a housing accommodating the circuit board therein, wherein
the metal member is accommodated in the housing.

11. An electronic device comprising:
a circuit board including a printed board and a noise source mounted on the printed board; and
a metal member providing an internal space accommodating the noise source and defining, between the metal member and the circuit board, a gap connecting the internal space to an external space,
wherein
the printed board includes a structure part including:
a ground layer providing a ground potential;
a land disposed to face the ground layer; and
a short-circuit portion electrically connecting the land and the ground layer,
the land is located closer to the gap than the ground layer, and
a facing distance between the structure part and the metal member at the gap is equal to or less than one quarter of a wavelength corresponding to a frequency of electromagnetic noise generated by the noise source.

12. An electronic device comprising:
a circuit board including a printed board and a noise source mounted on the printed board; and
a metal member providing an internal space accommodating the noise source and defining, between the metal member and the circuit board, a gap connecting the internal space to an external space,
wherein
the printed board includes a periodic structure part including:
a ground layer providing a ground potential;
a plurality of lands disposed to face the ground layer and disposed periodically along the gap; and
a plurality of short-circuit portions electrically connecting the plurality of lands to the ground layer, and
a facing distance between the periodic structure part and the metal member at the gap is greater than 0 mm and equal to or smaller than 12.5 mm.
